(19) United States
(12) Patent Application Publication
(10) Pub. No.: US 2025/0280702 A1
(43) Pub. Date: Sep. 4, 2025

(54) Electroluminescent Display Device

(71) Applicant: LG Display Co., Ltd., Seoul (KR)

(72) Inventor: Saehoon Oh, Paju-si (KR)

(21) Appl. No.: 18/807,809

(22) Filed: Aug. 16, 2024

(30) Foreign Application Priority Data
Feb. 29, 2024 (KR) 10-2024-0029989

(51) Int. Cl. H10K 59/80

(52) U.S. Cl. CPC H10K 59/80523; H10K 59/878; H10K 59/8791

(57) ABSTRACT

An electroluminescent display apparatus comprises a sub-pixel including a light emitting area and a circuit area, a first electrode in the light emitting area of the sub-pixel, a light emitting layer on the first electrode in the light emitting area of the sub-pixel, and a second electrode on the light emitting layer, the second electrode includes a first reflective layer overlapping the light emitting area and a second reflective layer overlapping the light emitting area and the circuit area, wherein a reflectance of a blue wavelength band of light of the first reflective layer is higher than a reflectance of the blue wavelength band of light of the second reflective layer.

### CROSS-REFERENCE TO RELATED APPLICATION

This application claims the priority of Republic of Korea Patent Application No. 10-2024-0029989, filed on Feb. 29, 2024, which is hereby incorporated by reference in its entirety.

### BACKGROUND

### Field

The present disclosure relates to an electroluminescent display device.

### Description of Related Art

An electroluminescent display device includes a first electrode, a second electrode, and a light emitting layer disposed between the first electrode and the second electrode, and displays an image by emitting light from the light emitting layer by an electric field between the two electrodes.

The electroluminescent display device may include a red sub-pixel, a green sub-pixel, and a blue sub-pixel to display images of various colors.

There is a need to increase a color temperature of light emitted in an on-state in which the image is displayed. In this case, even when external light is reflected, the color temperature increases, causing a problem that a reflection visibility of a reflected light decreases.

### SUMMARY

The present disclosure has been made in view of the above problems and it is an object of the present disclosure to provide an electroluminescent display device capable of increasing a color temperature of light in an on-state in which an image is displayed and improving a reflective visibility of external light in an off-state in which the image is not displayed.

In accordance with one or more embodiments of the present disclosure, the above and other objects can be accomplished by the provision of an electroluminescent display device comprising a sub-pixel including a light emitting area and a circuit area, a first electrode in the light emitting area of the first sub-pixel, a light emitting layer on the first electrode in the light emitting area of the sub-pixel, a second electrode on the light emitting layer, the second electrode includes a first reflective layer overlapping the light emitting area and a second reflective layer overlapping the light emitting area and the circuit area, wherein a reflectance of a blue wavelength band of light of the first reflective layer is higher than a reflectance of the blue wavelength band of light of the second reflective layer.

In addition, in accordance with one or more embodiments of the present disclosure, the above and other objects can be accomplished by the provision of an electroluminescent display device comprising a first sub-pixel and a second sub-pixel emitting light of different colors, a first electrode in the first sub-pixel, a first electrode in the second sub-pixel, a light emitting layer on the first electrode in the first sub-pixel and on the first electrode in the second sub-pixel, a second electrode in the first sub-pixel and on the light emitting layer, the second electrode in the first sub-pixel including a first reflective layer and a second reflective layer that is on the first reflective layer, and a second electrode in the second sub-pixel and on the light emitting layer, the second electrode in the second sub-pixel including a first reflective layer and the second reflective layer that is also included in the first subpixel, wherein the first reflective layer of the second electrode in the second sub-pixel is spaced apart from the first reflective layer of the second electrode in the first sub-pixel, and the second reflective layer is on the first reflective layer of the second electrode in the second sub-pixel.

In addition, in accordance with one or more embodiments of the present disclosure, the above and other objects can be accomplished by the provision of an electroluminescent display device comprising a substrate; and a sub-pixel on the substrate, the sub-pixel including a light emitting area that emits light, a circuit area that controls light emission from the light emitting area, a driving thin film transistor in the circuit area, a first electrode extending from the light emitting area to the circuit area, the first electrode connected to the driving thin film transistor, a light emitting layer on the first electrode in the light emitting area, and a second electrode on the light emitting layer, the second electrode including a first reflective layer and a second reflective layer on the first reflective layer, wherein the first reflective layer overlaps at least the light emitting area and the second reflective layer overlaps the light emitting area and the circuit area, and wherein a reflectance of the first reflective layer is different than a reflectance of the second reflective layer.

### BRIEF DESCRIPTION OF THE DRAWINGS

FIG. 1 is a schematic plan view of an electroluminescent display device according to one or more embodiments of the present disclosure.

FIG. 2 is a schematic cross-sectional view of an electroluminescent display device, which corresponds to a cross-section of line A-B of FIG. 1 according to one or more embodiments of the present disclosure.

FIG. 3 is a schematic cross-sectional view of an electroluminescent display device, which corresponds to a cross-section of line C-D of FIG. 1 according to one or more embodiments of the present disclosure.

FIG. 4 is a schematic cross-sectional view of an electroluminescent display device, which corresponds to a cross-section of line A-B of FIG. 1 according to one or more embodiments of the present disclosure.

FIG. 5 is a schematic cross-sectional view of an electroluminescent display device, which corresponds to a cross-section of line C-D of FIG. 1 according to one or more embodiments of the present disclosure.

FIG. 6 is a graph showing a change in reflectance for each wavelength band of a metal layer according to a change in a deposition rate according to one or more embodiments of the present disclosure.

FIG. 7 is a graph showing a change in a refractive index n for each wavelength band of a metal layer according to a change in a deposition rate according to one or more embodiments of the present disclosure.

FIG. 8 is a graph showing a change in a refractive index k for each wavelength band of a metal layer according to a change in a deposition rate according to one or more embodiments of the present disclosure.

FIG. 9 is a graph showing a change in reflectance for each wavelength band of an electroluminescent display device when a metal layer is applied as a second electrode (cathode) according to a change in a deposition rate according to one or more embodiments of the present disclosure.

FIG. 10 is a graph showing an emission intensity for each wavelength band of an electroluminescent display device when a metal layer is applied as a second electrode (cathode) according to a change in a deposition rate according to one or more embodiments of the present disclosure.

FIG. 11 is a graph showing a change in refractive index n for each wavelength band of a metal layer according to a change in a deposition rate in the range of 1.7 Å/s to 2.0 Å/s according to one or more embodiments of the present disclosure.

FIG. 12 is a graph showing a change in refractive index k for each wavelength band of a metal layer according to a change in a deposition rate in the range of 1.7 Å/s to 2.0 Å/s according to one or more embodiments of the present disclosure.

FIG. 13 is a graph showing a change in reflectance for each wavelength band of an electroluminescent display device when a metal layer is applied as a second electrode (cathode) according to a change in a deposition rate in the range of 1.7 Å/s to 2.0 Å/s according to one or more embodiments of the present disclosure.

FIG. 14 is a graph showing a change in refractive index n for each wavelength band of a metal layer according to a change in a deposition rate in the range of 3.0 Å/s to 3.7 Å/s according to one or more embodiments of the present disclosure.

FIG. 15 is a graph showing a change in refractive index k for each wavelength band of a metal layer according to a change in a deposition rate in the range of 3.0 Å/s to 3.7 Å/s according to one or more embodiments of the present disclosure.

FIG. 16 is a graph showing a change in reflectance for each wavelength band of an electroluminescent display device when a metal layer is applied as a second electrode (cathode) according to a change in a deposition rate in the range of 3.0 Å/s to 3.7 Å/s according to one or more embodiments of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only’ is used. The terms of a singular form may include plural forms unless referred to the contrary.

In construing an element, the element is construed as including an error band although there is no explicit description.

In describing a position relationship, for example, when the position relationship is described as ‘upon’, ‘above’, ‘below’ and ‘next to’, one or more portions may be disposed between two other portions unless ‘just’ or ‘direct’ is used.

In the case of a description of a temporal relationship, for example, if the temporal precedence relationship is described as ‘after’, ‘subsequently’, ‘next to’, and ‘before’, or if it is not continuous unless ‘right’ or ‘direct’ is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Hereinafter, embodiments of the present disclosure will be described in detail with reference to the accompanying drawings.

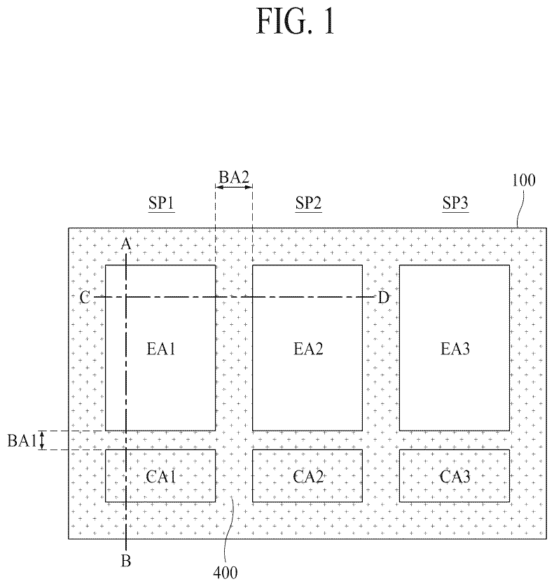

FIG. 1 is a schematic plan view of an electroluminescent display device according to one or more embodiments of the present disclosure.

As shown in FIG. 1, the electroluminescent display device according to one or more embodiments of the present disclosure includes a plurality of sub-pixels SP1, SP2, and SP3 disposed on a substrate 100.

The plurality of sub-pixels SP1, SP2, and SP3 include a plurality of light emitting areas EA1, EA2, and EA3 and a plurality of circuit areas CA1, CA2, and CA3. The plurality of light emitting areas EA1, EA2, and EA3 are areas where light emission is performed, and the plurality of circuit areas CA1, CA2, and CA3 are areas that control light emission from the plurality of light emitting areas EA1, EA2, and EA3.

The plurality of sub-pixels SP1, SP2, and SP3 include a first sub-pixel SP1 emitting light of a first color, a second sub-pixel SP2 emitting light of a second color, and a third sub-pixel SP3 emitting light of a third color. Any one of the first color, the second color, and the third color may be red, another may be green, and the other may be blue. The shapes and arrangements of the first sub-pixel SP1, the second sub-pixel SP2, and the third sub-pixel SP3 may be changed by various methods known in the art. In addition, a fourth sub-pixel emitting light of a fourth color in addition to the first sub-pixel SP1, the second sub-pixel SP2, and the third sub-pixel SP3 may be additionally disposed.

The first sub-pixel SP1 includes a first light emitting area EA1 for emitting light of the first color and a first circuit area CA1 for controlling light emission in the first light emitting area EA1, the second sub-pixel SP2 includes a second light emitting area EA2 for emitting light of the second color and a second circuit area CA2 for controlling light emission in the second light emitting area EA2, and the third sub-pixel SP3 includes a third emitting area EA3 for emitting light of the third color and a third circuit area CA3 for controlling light emission in the third emitting area EA3.

Although the drawing shows the circuit areas CA1, CA2, and CA3 disposed below the light emitting areas EA1, EA2, and EA3, it is not limited thereto.

A first boundary area BA1 may be disposed between the circuit areas CA1, CA2, and CA3 and the light emitting areas EA1, EA2, and EA3. Also, a second boundary area BA2 may be disposed between the first sub-pixel SP1, the second sub-pixel SP2, and the third sub-pixel SP3. For example, the second boundary area BA2 may be disposed between the first sub-pixel SP1 and the second sub-pixel SP2 and between the second sub-pixel SP2 and the third sub-pixel SP3.

A bank 400 may be disposed in the first boundary area BA1, the second boundary area BA2, and the circuit areas CA1, CA2, and CA3. That is, the bank 400 may be formed in an entire area except for the light emitting areas EA1, EA2, and EA3 within a display area for displaying an image. An opening area not covered by the bank 400 may correspond to the light emitting areas EA1, EA2, and EA3.

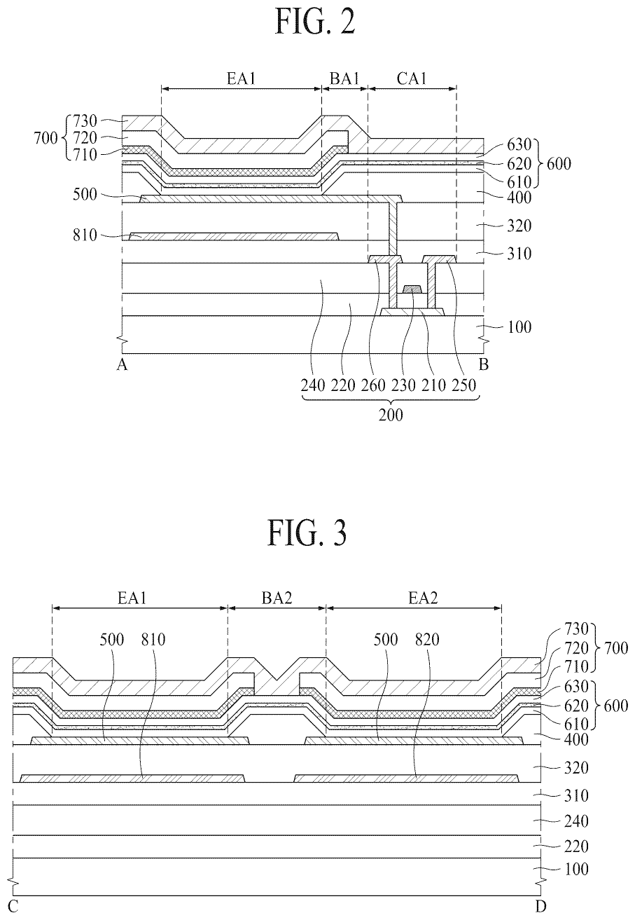

FIG. 2 is a schematic cross-sectional view of an electroluminescent display device according to one or more embodiments of the present disclosure, which corresponds to a cross-section of line A-B of FIG. 1. That is, FIG. 2 is a cross-sectional view of the first sub-pixel SP1 in FIG. 1.

As shown in FIG. 2, the electroluminescent display device according to an embodiment of the present disclosure includes a substrate 100, a circuit element layer 200, a passivation layer 310, a planarization layer 320, a bank 400, a first electrode 500, a light emitting layer 600, a second electrode 700, and a first color filter 810.

The substrate 100 may be made of glass or plastic, but is not necessarily limited thereto. The electroluminescent display device according to an embodiment of the present disclosure may be a bottom emission type, and accordingly, a transparent material may be used as a material of the substrate 100.

The circuit element layer 200 is disposed on the substrate 100.

The circuit element layer 200 includes a driving thin film transistor. The driving thin film transistor overlaps the first circuit area CA1.

The driving thin film transistor includes an active layer 210 disposed on the substrate 100, a gate insulating layer 220 disposed on the active layer 210, a gate electrode 230 disposed on the gate insulating layer 220, an interlayer insulating layer 240 disposed on the gate electrode 230, and a source electrode 260 and a drain electrode 250 disposed on the interlayer insulating layer 240. The source electrode 260 and the drain electrode 250 are connected with one side and the other side of the active layer 210 through holes disposed in the interlayer insulating layer 240 and the gate insulating layer 220.

Although the driving thin film transistor having a top gate structure in which the gate electrode 230 is disposed on the active layer 210 is illustrated in FIG. 2, the present disclosure may include a driving thin film transistor having a bottom gate structure in which the gate electrode 230 is disposed under the active layer 210. Also, although the gate insulating layer 220 is formed on an entire surface of the first substrate 100 in FIG. 2, the gate insulating layer 220 may be patterned in the same shape as the gate electrode 230 below the gate electrode 230. The driving thin film transistor may be changed in various forms known in the art.

The active layer 210, the gate electrode 230, the source electrode 260, and the drain electrode 250 constituting the driving thin film transistor may overlap the first circuit area CA1 and may not overlap the first light emitting area EA1.

In addition, although not shown, the circuit element layer 200 may further include various signal lines including a gate line, a data line, a power line, and a reference line, various thin film transistors including a switching thin film transistor and a sensing thin film transistor, and a capacitor, in addition to the driving thin film transistor. The various signal lines, electrodes included in the switching thin film transistor, electrodes included in the sensing thin film transistor, and electrodes included in the capacitor may overlap the first circuit area CA1 and may not overlap the first light emitting area EA1.

The switching thin film transistor is switched according to a gate signal supplied to the gate line to supply a data voltage supplied from the data line to the driving thin film transistor.

The driving thin film transistor is switched according to the data voltage supplied from the switching thin film transistor. And, the driving thin film transistor generates a data current from a power source supplied from a power line and supplies the data current to the first electrode 500.

The sensing thin film transistor senses a threshold voltage deviation of the driving thin film transistor that causes image quality deterioration. In addition, the sensing thin film transistor supplies a current of the driving thin film transistor to a reference line in response to a sensing control signal supplied from the gate line or a separate sensing line.

The capacitor maintains the data voltage supplied to the driving thin film transistor for one frame, and is connected with a gate terminal and a source terminal of the driving thin film transistor, respectively.

The passivation layer 310 is disposed on the circuit element layer 200. Specifically, the passivation layer 310 is disposed on the source electrode 260 and the drain electrode 250.

The planarization layer 320 is disposed on the passivation layer 310. The passivation layer 310 may be made of an inorganic insulating material, and the planarization layer 320 may be made of an organic insulating material, but is not limited thereto.

The passivation layer 310 and the planarization layer 320 may include a contact hole, and the source electrode 260 may be exposed by the contact hole, and the first electrode 500 may be connected with exposed source electrode 260 through the contact hole. In some cases, the drain electrode 250 may be exposed through a contact hole disposed in the passivation layer 310 and the planarization layer 320, and the first electrode 500 may be connected with exposed drain electrode 250 through the contact hole.

The bank 400 is disposed on the planarization layer 320 and the first electrode 500 and covers an edge of the first electrode 500. The first light emitting area EA1 may be defined by the bank 400. That is, a portion of the first electrode 500 exposed without being covered by the bank 400 may become the first light emitting area EA1. Thus, the bank 400 may overlap the first boundary area BA1 and the first circuit area CA1.

The first electrode 500 is disposed on the planarization layer 320. The first electrode 500 may overlap the entire first light emitting area EA1, pass through the first boundary area BA1, and extend to one part of the first circuit area CA1. Accordingly, in the first circuit area CA1, the first electrode 500 is connected with the source electrode 260 or the drain electrode 250 through contact holes disposed in the passivation layer 310 and the planarization layer 320.

The first electrode 500 may include a transparent electrode or a translucent electrode. Accordingly, the light emitted from the light emitting layer 600 may pass through the first electrode 500 in the first light emitting area EA1 and move downward. The first electrode 500 may be formed of a single layer or a plurality of layers.

The light emitting layer 600 is disposed on the first electrode 500 and the bank 400. The light emitting layer 600 may overlap the entire first light emitting area EA1, the entire first boundary area BA1, and the entire first circuit area CA1.

The light emitting layer 600 may be disposed to emit white light, but is not necessarily limited thereto. The light emitting layer 600 may be disposed to be continuous without being disconnected between all sub-pixels.

The light emitting layer 600 may include a first stack 610, a charge generation layer 620, and a second stack 630. The first stack 610 may be disposed on the first electrode 500 and the bank 400, the charge generation layer 620 may be disposed on the first stack 610, and the second stack 630 may be disposed on the charge generation layer 620.

The first stack 610 may emit one light of blue and yellow-green, and the second stack 630 may emit the other light of blue and yellow-green. For example, the first stack 610 may emit blue light, and the second stack 630 may emit yellow-green light. In some cases, the second stack 630 may emit a mixed light of yellow-green light and red light.

Each of the first stack 610 and the second stack 630 may include at least one of a hole injection layer, a hole transport layer, an electron blocking layer, an organic emission layer, a hole blocking layer, an electron transport layer, and an electron injection layer.

The charge generation layer 620 may include an N-type charge generation layer disposed on the first stack 610 to supply electrons to the first stack 610, and a P-type charge generation layer disposed on the N-type charge generation layer to supply holes to the second stack 630.

As shown, the light emitting layer 600 is not limited to the two stack structure, and may have a stack structure including three or more stacks and two or more charge generation layers.

The second electrode 700 is disposed on the light emitting layer 600.

The second electrode 700 includes a first reflective layer 710, a transmissive layer 720, and a second reflective layer 730.

The first reflective layer 710 may be disposed on the light emitting layer 600 and may overlap the entire first light emitting area EA1. The first reflective layer 710 may extend to at least a portion of the first boundary area BA1, but not to the first circuit area CA1. Thus, the first reflective layer 710 does not overlap the first circuit area CA1. In some cases, the first reflective layer 710 may not extend to the first boundary area BA1 and may not overlap the first boundary area BA1. The first reflective layer 710 may be formed of a metallic material.

The transmissive layer 720 may be disposed on the first reflective layer 710 and may be formed in the same pattern as the first reflective layer 710. Accordingly, the transmissive layer 720 may overlap the entire first light emitting area EA1 and extend to at least a portion of the first boundary area BA1, but may not extend to the first circuit area CA1. Thus, the transmissive layer 720 may not overlap the first circuit area CA1. In some cases, the first reflective layer 710 also may not overlap the first boundary area BA1. Meanwhile, the transmissive layer 720 may be formed in a different pattern from the first reflective layer 710. The transmissive layer 720 may be formed of a transparent conductive material, but is not limited thereto.

The second reflective layer 730 is disposed on the transmissive layer 720. The second reflective layer 730 may overlap the entire first light emitting area EA1, the entire first boundary area BA1, and the entire first circuit area CA1 and may be formed to be continuous from the first light emitting area EA1 to the first circuit area CA1. Accordingly, a lower surface of the second reflective layer 730 may be in contact with an upper surface of the transmissive layer 720 in the entire first light emitting area EA1 and a part of the first boundary area BA1, but the lower surface of the second reflective layer 730 may be in contact with an upper surface of the light emitting layer 600 in a remaining part of the first boundary area BA1 and the entire first circuit area CA1. The second reflective layer 730 may be formed of a metallic material.

It is necessary to increase a color temperature of white light in displaying an image. In order to increase the color temperature of white light, it is advantageous that a reflectance of blue light in a short-wavelength band is higher than a reflectance of green light in a medium-wavelength band and a reflectance of red light in a long-wavelength band, when the light emitted from the light emitting layer 600 reflects light from the second electrode 700. However, when external light is reflected in an off-state in which an image is not display, if the reflectance of blue light in short wavelength band by the second electrode 700 is high, a color of the reflected external light may be shifted toward blue. Accordingly, a reflection visibility of the display device can be deteriorated.

According to one or more embodiments of the present disclosure, the first reflective layer 710 overlaps the entire first light emitting area EA1, but the first reflective layer 710 does not extend to the first circuit area CA1. Also, the second reflective layer 730 overlaps the entire first circuit area CA1. Accordingly, the light emitted from the light emitting layer 600 is reflected from the first reflective layer 710 in an on-state in which the image is displayed, and the external light is reflected from the first reflective layer 710 and the second reflective layer 730 in the off-state in which the image is not displayed. In this case, by configuring a reflectance of the first reflective layer 710 for each wavelength band of light to be different from a reflectance of the second reflective layer 730 for each wavelength band of light, the color temperature of the white light may be increased in the on-state in which the image is displayed, and the problem in which the color of the external light is shifted toward the blue in the off-state in which the image is not displayed may be reduced.

More specifically, according to one or more embodiments of the present disclosure, the reflectance of the first reflective layer 710 for the short wavelength band of blue light, for example 450 nm may be higher than the reflectance of the second reflective layer 730 for the short wavelength band of blue light, for example 450 nm. Accordingly, in the on state in which the image is displayed, the reflectance for the short wavelength band of blue light among light emitted from the light emitting layer 600 and reflected from the first reflective layer 710 may increase, and then the color temperature of white light may increase. In addition, in the off-state in which the image is not displayed, the external light may also be reflected from the second reflective layer 730. Accordingly, the reflectance for the short wavelength band of blue light among the reflected external light is relatively reduced, thereby reducing the problem in which the color of the external light is shifted toward blue.

In addition, the reflectance of the first reflective layer 710 for the long wavelength band of red light, for example 650 nm may be lower than the reflectance of the second reflective layer 730 for the long wavelength band of red light, for example 650 nm.

In this way, the reflectance of the second reflective layer 730 for the long-wavelength light is higher than the reflectance of the first reflective layer 710 for the long-wavelength light. Accordingly, when the external light is reflected from the second reflective layer 730 in the off-state in which the image is not displayed, the reflectance for the long-wavelength light may increase. Therefore, the problem in which the color of the external light is shifted toward blue is reduced.

The first reflective layer 710 and the second reflective layer 730 may be made of the same metal, for example, aluminum (Al). In particular, the first reflective layer 710 and the second reflective layer 730 may be formed by the same deposition process, for example, the same sputtering process. In this case, by forming a deposition rate of the first reflective layer 710 to be different from a deposition rate of the second reflective layer 730, the first reflective layer 710 and the second reflective layer 730 having different reflectance characteristics for each wavelength band of light may be obtained as described above.

Specifically, during a metal deposition process, when a deposition rate of the metal is relatively low, the reflectance for the short-wavelength band of blue light may be relatively high, compared to a case when the deposition rate of the metal is high. In addition, during the metal deposition process, when the deposition rate of the metal is high, the reflectance for the long-wavelength band of red light may be relatively high compared to a case where the deposition rate of the metal is low.

According to one or more embodiments of the present disclosure, the deposition rate of the first reflective layer 710 is lower than the deposition rate of the second reflective layer 730. In particular, by configuring the deposition rate of the first reflective layer 710 in the range of 1.7 Å/s to 2.0 Å/s, the color temperature of white light emitted may be increased to 8,000 K or more in the on-state in which the image is displayed. Furthermore, by configuring the deposition rate of the second reflective layer 730 in the range of 3.0 Å/s to 3.7 Å/s, the color temperature of external light may be lowered to less than 7100 K in the off-state in which the image is not displayed. A change of the color temperature according to a change of the deposition rate will be described later.

The first color filter 810 may be disposed between the passivation layer 310 and the planarization layer 320, but is not limited thereto. The electroluminescent display device according to one or more embodiments of the present disclosure may be the bottom emission type, and accordingly, the first color filter 810 is disposed below the first electrode 500 while overlapping the first light emitting area EA1. For example, the first color filter 810 may be disposed between the interlayer insulating layer 240 and the passivation layer 310, or may be disposed between the gate insulating layer 220 and the interlayer insulating layer 240.

The first color filter 810 may be formed of any one of a red color filter, a green color filter, and a blue color filter.

FIG. 3 is a schematic cross-sectional view of an electroluminescent display device, which corresponds to a cross-section of line C-D of FIG. 1 according to one or more embodiments of the present disclosure. That is, FIG. 3 illustrate cross-sections of the first light emitting area EA1 and the second light emitting area EA2 in FIG. 1.

As shown in FIG. 3, the electroluminescent display device according to one or more embodiments of the present disclosure includes a substrate 100, a gate insulating film 220, an interlayer insulating film 240, a passivation layer 310, a planarization layer 320, a bank 400, a first electrode 500, a light emitting layer 600, a second electrode 700, a first color filter 810, and a second color filter 820.

The gate insulating layer 220 is disposed on the substrate 100, the interlayer insulating layer 240 is disposed on the gate insulating layer 220, the passivation layer 310 is disposed on the interlayer insulating layer 240, and the planarization layer 320 is disposed on the passivation layer 310.

The bank 400 is disposed on the planarization layer 320 and the first electrode 500 and covers an edge of the first electrode 500. A first light emitting area EA1 and a second light emitting area EA2 may be defined by the bank 400. The bank 400 may overlap the second boundary area BA2 between the first light emitting area EA1 and the second light emitting area EA2.

The first electrode 500 is patterned in each of the first light emitting area EA1 and the second light emitting area EA2 on the planarization layer 320. The first electrode 500 of the first light emitting area EA1 extends to the second boundary area BA2 while overlapping the entire first light emitting area EA1, and the first electrode 500 of the second light emitting area EA2 extends to the second boundary area BA2 while overlapping the entire second light emitting area EA2.

The light emitting layer 600 may be disposed on the first electrode 500 and the bank 400 and may overlap the entire first light emitting area EA1, the entire second light emitting area EA2, and the entire second boundary area BA2. The light emitting layer 600 may include a first stack 610, a charge generation layer 620, and a second stack 630.

The second electrode 700 is disposed on the light emitting layer 600.

The second electrode 700 includes a first reflective layer 710, a transmission layer 720 disposed on the first reflective layer 710, and a second reflective layer 730 disposed on the transmission layer 720.

The first reflective layer 710 is patterned in each of the first light emitting area EA1 and the second light emitting area EA2.

The first reflective layer 710 disposed in the first light emitting area EA1 may overlap the entire first light emitting area EA1 and may overlap a part of the second boundary area BA2. Also, the first reflective layer 710 disposed in the second light emitting area EA2 may overlap the entire second light emitting area EA2 and may overlap a part of the second boundary area BA2. The first reflective layer 710 disposed in the first light emitting area EA1 is spaced apart from the first reflective layer 710 disposed in the second light emitting area EA2 with the second reflective layer 730 therebetween.

The transmissive layer 720 is patterned in each of the first light emitting area EA1 and the second light emitting area EA2.

The transmissive layer 720 disposed in the first light emitting area EA1 may overlap the entire first light emitting area EA1 and may overlap a portion of the second boundary area BA2. Also, the transmissive layer 720 disposed in the second light emitting area EA2 may overlap the entire second light emitting area EA2 and may overlap a portion of the second boundary area BA2. The transmissive layer 720 disposed in the first light emitting area EA1 is spaced apart from the transmissive layer 720 disposed in the second light emitting area EA2 with the second reflective layer 730 therebetween.

The second reflective layer 730 may be formed to continuously extend from the first light emitting area EA1 to the second light emitting area EA2 while overlapping the entire first light emitting area EA1, the entire second boundary area BA2, and the entire second light emitting area EA2. Accordingly, a lower surface of the second reflective layer 730 may be in contact with an upper surface of the transmissive layer 720 in the entire first light emitting area EA1, the entire second light emitting area EA2, and a part of the second boundary area BA2, but may be in contact with an upper surface of the light emitting layer 600 in a remaining part of the second boundary area BA2.

The first color filter 810 is disposed in the first light emitting area EA1, and the second color filter 820 is disposed in the second light emitting area EA2.

The first color filter 810 and the second color filter 820 are disposed below the first electrode 500. For example, the first color filter 810 and the second color filter 820 may be disposed between the gate insulating layer 220 and the interlayer insulating layer 240, between the interlayer insulating layer 240 and the passivation layer 310, or between the passivation layer 310 and the planarization layer 320. The first color filter 810 may be formed of any one of a red color filter, a green color filter, and a blue color filter, and the second color filter 820 may be formed of the other.

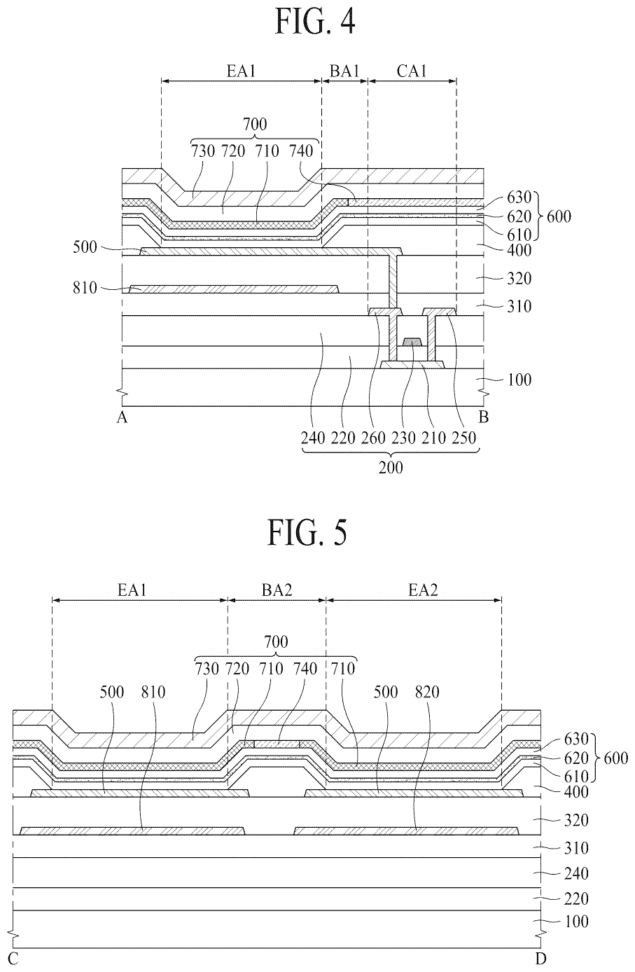

FIG. 4 is a schematic cross-sectional view of an electroluminescent display device, which corresponds to a cross-section of line A-B of FIG. 1 according to one or more embodiments of the present disclosure.

FIG. 4 is the same as the electroluminescent display device according to FIG. 2 described above, except that the configuration of the second electrode 700 is changed. Therefore, the same reference numerals are given to the same configuration, and hereinafter, only different configurations will be described.

As shown in FIG. 4, the second electrode 700 includes a first reflective layer 710, a transmissive layer 720, a second reflective layer 730, and a third reflective layer 740.

Since the first reflective layer 710 is the same as FIG. 2 described above, repeated descriptions thereof will be omitted.

The third reflective layer 740 may be disposed in an area where the first reflective layer 710 is not disposed. Therefore, the third reflective layer 740 may be formed to be in contact with the upper surface of the light emitting layer 600 while overlapping at least a portion of the first boundary area BA1 and the entire first circuit area CA1.

The third reflective layer 740 may be connected with the first reflective layer 710, and may have the same thickness as the first reflective layer 710. The third reflective layer 740 may be formed of a metallic material. An upper surface of the third reflective layer 740 may be aligned with an upper surface of the first reflective layer 710.

The transmissive layer 720 may be disposed on the first reflective layer 710 and the third reflective layer 740. The transmissive layer 720 may be formed to continuously extend from the first light emitting area EA1 to the first circuit area CA1 while overlapping the entire first light emitting area EA1, the entire first boundary area BA1, and the entire first circuit area CA1.

The second reflective layer 730 may be disposed on the transmissive layer 720, and may be formed to continuously extend from the first light emitting area EA1 to the first circuit area CA1 while overlapping the entire first light emitting area EA1, the entire first boundary area BA1, and the entire first circuit area CA1. The second reflective layer 730 may be formed in the same pattern as the transmissive layer 720.

According to one or more embodiments of the present disclosure, the first reflective layer 710 overlaps the entire first light emitting area EA1 but does not extend to the first circuit area CA1, and the third reflective layer 740 overlaps the entire first circuit area CA1. Accordingly, the light emitted from the light emitting layer 600 reflects from the first reflective layer 710 in the on-state in which the image is displayed, and the external light reflects from the first reflective layer 710 and the third reflective layer 740 in the off-state in which the image is not displayed. In this case, by configuring the reflectance of the first reflective layer 710 for each wavelength band of light to be different from the reflectance of the third reflective layer 740 for each wavelength band of light, the color temperature of white light is increased in the on-state in which the image is displayed, and the problem of the color of external light shifting toward blue in the off-state in which the image is not displayed is reduced.

More specifically, according to one or more embodiments of the present disclosure, the reflectance of the first reflective layer 710 for the short wavelength band of blue light, for example 450 nm may be higher than the reflectance of the third reflective layer 740 for the short wavelength band of blue light, for example 450 nm. Accordingly, in the on state in which the image is displayed, the reflectance for the short wavelength band of blue light among light emitted from the light emitting layer 600 and reflected from the first reflective layer 710 may increase, and then the color temperature of white light may increase. In addition, in the off-state in which the image is not displayed, the external light may also be reflected from the third reflective layer 740. Accordingly, the reflectance for the short wavelength band of blue light among the reflected external light is relatively reduced, thereby reducing the problem in which the color of the external light is shifted toward blue.

In addition, the reflectance of the first reflective layer 710 for the long wavelength band of red light, for example 650 nm may be lower than the reflectance of the third reflective layer 740 for the long wavelength band of red light, for example 650 nm.

In this way, the reflectance of the third reflective layer 740 for the long-wavelength light is higher than the reflectance of the first reflective layer 710 for the long-wavelength light. Accordingly, when the external light is reflected from the third reflective layer 740 in the off-state in which the image is not displayed, the reflectance for the long-wavelength light may increase. Therefore, the problem in which the color of the external light is shifted toward blue is reduced.

The first reflective layer 710 and the third reflective layer 740 may be made of the same metal, for example, aluminum (Al). In particular, the first reflective layer 710 and the third reflective layer 740 may be formed by the same deposition process, for example, the same sputtering process. In this case, by forming a deposition rate of the first reflective layer 710 to be different from a deposition rate of the third reflective layer 740, the first reflective layer 710 and the third reflective layer 740 having different reflectance characteristics for each wavelength band of light may be obtained as described above.

Specifically, the deposition rate of the first reflective layer 710 is less than the deposition rate of the third reflective layer 740. In particular, by configuring the deposition rate of the first reflective layer 710 in the range of 1.7 Å/s to 2.0 Å/s, the color temperature of white light emitted may be increased to 8,000 K or more in the on-state in which the image is displayed. Furthermore, by configuring the deposition rate of the third reflective layer 740 in the range of 3.0 Å/s to 3.7 Å/s, the color temperature of external light may be lowered to less than 7100 K in the off-state in which the image is not displayed.

The deposition rate of the third reflective layer 740 may be the same as the deposition rate of the second reflective layer 730, and in this case, the third reflective layer 740 may be the same as the second reflective layer 730.

In both the structures of FIG. 2 and FIG. 4, a portion of the external light may be transmitted through the first reflective layer 710 in the first light emitting area EA1, and in this case, a portion of the transmitted external light may be reflected from the second reflective layer 730 disposed above the first reflective layer 710. Accordingly, when the external light is reflected, the reflectance for the long-wavelength light increases, and thus the problem that the color of the external light is shifted toward the blue is reduced. Accordingly, a structure in which the second reflective layer 730 is disposed on the first reflective layer 710 in the first light emitting area EA1 may be effective in reducing the problem that the color of external light is shifted toward blue. Similarly, in the structure of FIG. 4, a structure in which the second reflective layer 730 is disposed on the third reflective layer 740 in the first boundary area BA1 and the first circuit area CA1 may be effective in reducing the problem that the color of external light is shifted toward blue.

FIG. 5 is a schematic cross-sectional view of an electroluminescent display device, which corresponds to a cross-section of line C-D of FIG. 1 according to one or more embodiments of the present disclosure.

FIG. 5 is the same as the electroluminescent display device according to FIG. 3 described above, except that the configuration of the second electrode 700 is changed. Therefore, the same reference numerals are given to the same configuration, and hereinafter, only different configurations will be described.

As shown in FIG. 5, the second electrode 700 includes a first reflective layer 710, a transmissive layer 720, a second reflective layer 730, and a third reflective layer 740.

The first reflective layer 710 is patterned in each of the first light emitting area EA1 and the second light emitting area EA2 as in FIG. 3 described above.

The third reflective layer 740 may be disposed in an area where the first reflective layer 710 is not disposed. Accordingly, the third reflective layer 740 may be formed to be in contact with the upper surface of the light emitting layer 600 while overlapping at least a portion of the second boundary area BA2. Therefore, the first reflective layer 710 disposed in the first light emitting area EA1 is spaced apart from the first reflective layer 710 disposed in the second light emitting area EA2 with the third reflective layer 740 therebetween.

The transmissive layer 720 may be disposed on the first reflective layer 710 and the third reflective layer 740. The transmissive layer 720 may be formed to continuously extend from the first light emitting area EA1 to the second light emitting area EA2 while overlapping the entire first light emitting area EA1, the entire second boundary area BA2, and the entire second light emitting area EA2.

The second reflective layer 730 may be formed to continuously extend from the first light emitting area EA1 to the second light emitting area EA2 while overlapping the entire first light emitting area EA1, the entire second boundary area BA2, and the entire second light emitting area EA2. The second reflective layer 730 may be formed in the same pattern as the transmissive layer 720.

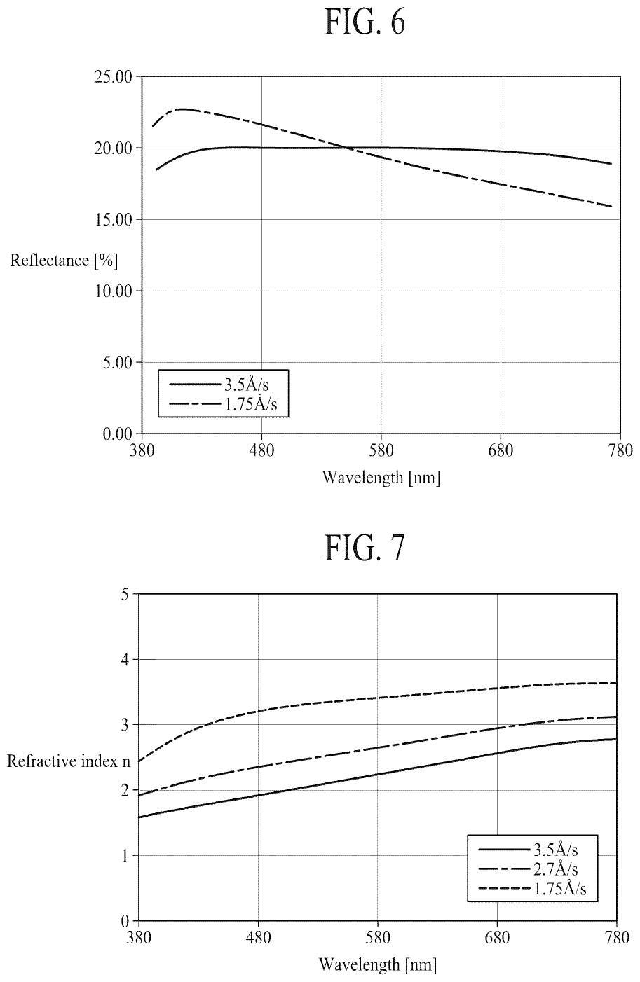

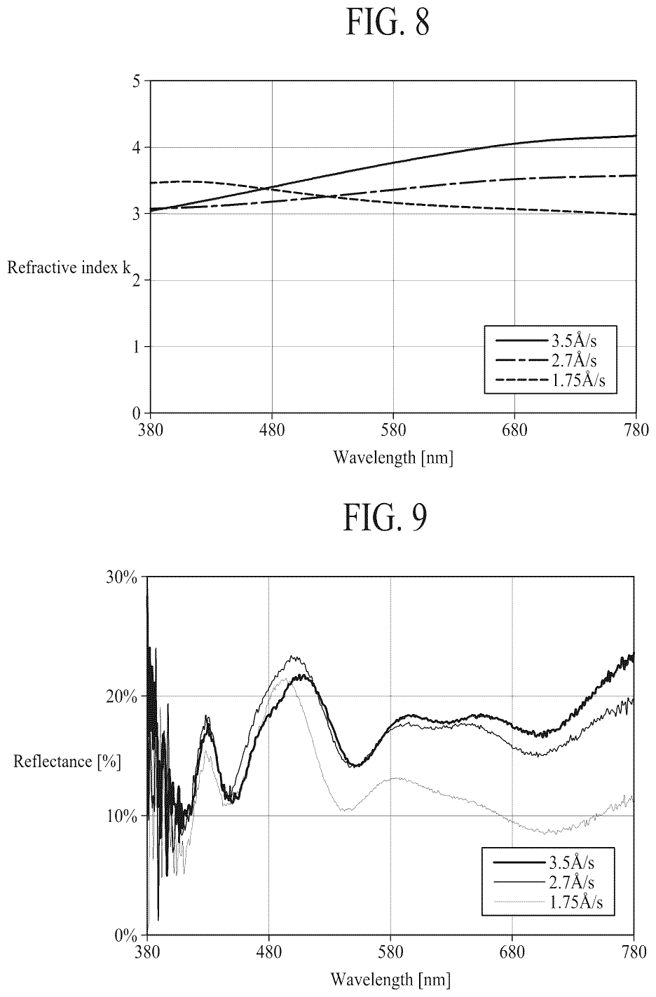

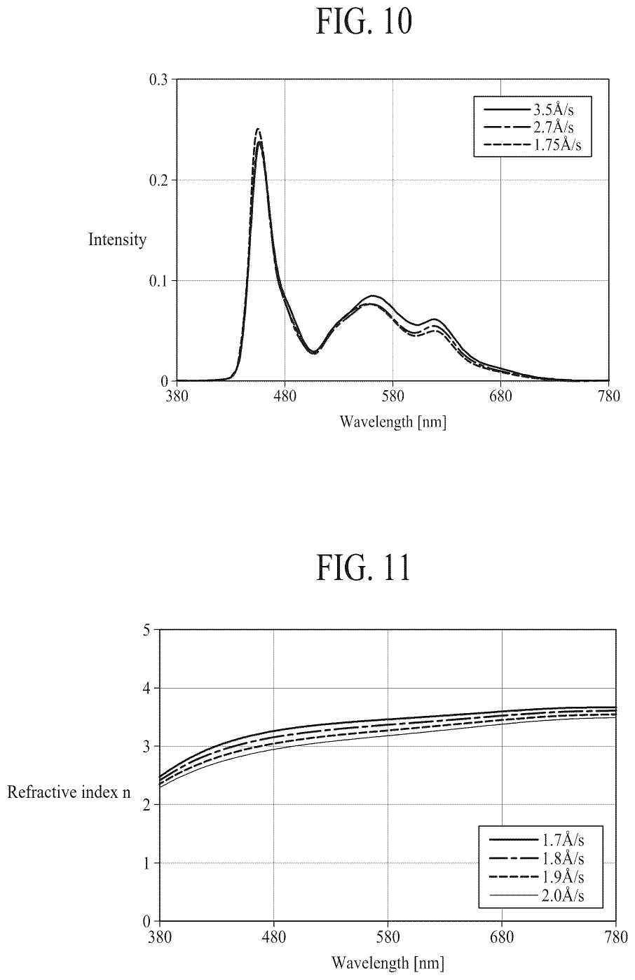

FIGS. 6 to 10 are graphs showing various optical characteristics according to a change in a deposition rate of aluminum (Al) as a metal layer according to one or more embodiments of the present disclosure. Specifically, FIG. 6 is a graph showing a change in reflectance for each wavelength band of a metal layer according to a change in a deposition rate according to one or more embodiments of the present disclosure, FIG. 7 is a graph showing a change in a refractive index n for each wavelength band of a metal layer according to a change in a deposition rate according to one or more embodiments of the present disclosure, FIG. 8 is a graph showing a change in a refractive index k for each wavelength band of a metal layer according to a change in a deposition rate according to one or more embodiments of the present disclosure, FIG. 9 is a graph showing a change in reflectance for each wavelength band of an electroluminescent display device when a metal layer is applied as a second electrode (cathode) according to a change in a deposition rate according to one or more embodiments of the present disclosure, and FIG. 10 is a graph showing an emission intensity for each wavelength band of an electroluminescent display device when a metal layer is applied as a second electrode (cathode) according to a change in a deposition rate according to one or more embodiments of the present disclosure. The results according to FIGS. 6 to 10 are shown in Table 1 below.

As shown in FIG. 6, the reflectance of the metal layer having a relatively high deposition rate of 3.5 Å/s increases minutely and then decreases minutely again from a short wavelength band to a long wavelength band. In addition, the reflectance of the metal layer having a relatively low deposition rate of 1.75 Å/s generally decreases from about 400 nm to longer length band.

Specifically, in the short wavelength band (450 nm), the reflectance of the metal layer of 1.75 Å/s is higher than the reflectance of the metal layer of 3.5 Å/s, but in the medium wavelength band (550 nm) and the long wavelength band (650 nm), the reflectance of the metal layer of 1.75 Å/s is lower than the reflectance of the metal layer of 3.5 Å/s.

As shown in FIG. 7 and Table 1, both of the refractive index n of the metal layer of 3.5 Å/s, the refractive index n of the metal layer of 2.7 Å/s, and the refractive index n of the metal layer of 1.75 Å/s increase from the short wavelength band to the long wavelength band.

Specifically, the refractive index n of the metal layer of 1.75 Å/s is higher than the refractive index n of the metal layer of 2.7 Å/s and the refractive index n of the metal layer of 3.5 Å/s in the short wavelength band 450 nm, the medium wavelength band 550 nm, and the long wavelength band 650 nm. Furthermore, the refractive index n of the metal layer of 2.7 Å/s is higher than the refractive index n of the metal layer of 3.5 Å/s in the short wavelength band 450 nm, the medium wavelength band 550 nm, and the long wavelength band 650 nm.

As can be seen from FIG. 8 and Table 1, the refractive index k of the metal layer of 3.5 Å/s and the refractive index k of the metal layer of 2.7 Å/s increase, but the refractive index k of the metal layer of 1.75 Å/s decreases from the short wavelength band to the long wavelength band.

Specifically, in the short wavelength band (450 nm), the refractive index k of the metal layer of 1.75 Å/s is higher than the refractive index k of the metal layer of 3.5 Å/s and the refractive index k of the metal layer of 2.7 Å/s, but in the medium wavelength band (550 nm) and the long wavelength band (650 nm), the refractive index k of the metal layer of 1.75 Å/s is lower than the refractive index k of the metal layer of 3.5 Å/s and the refractive index k of the metal layer of 2.7 Å/s.

As shown in FIG. 9 and Table 1, in the short wavelength band (450 nm), the reflectance of the electroluminescent display device with the metal layer of 1.75 Å/s is higher than the reflectance of the electroluminescent display device with the metal layer of 3.5 Å/s and the reflectance of the electroluminescent display device with the metal layer of 2.7 Å/s, but in the long wavelength band (650 nm), the reflectance of the electroluminescent display device with the metal layer of 3.5 Å/s is higher than the reflectance of the electroluminescent display device with the metal layer of 1.75 Å/s and the reflectance of the electroluminescent display device with the metal layer of 2.7 Å/s. On average, the reflectance of the electroluminescent display device with the metal layer of 1.75 Å/s is 14.4%, the reflectance of the electroluminescent display device with the metal layer of 3.5 Å/s is 14.1%, and the reflectance of the electroluminescent display device with the metal layer of 2.7 Å/s is 14.0%.

As shown in FIG. 10, in the short wavelength band (450 nm), the emission intensity of the electroluminescent display device with the metal layer of 1.75 Å/s is greater than the emission intensity of the electroluminescent display device with the metal layer of 3.5 Å/s and the emission intensity of the electroluminescent display device with the metal layer of 2.7 Å/s, but in the medium wavelength band (550 nm) and the long wavelength band (650 nm), the emission intensity of the electroluminescent display device with the metal layer of 3.5 Å/s is greater than the emission intensity of the electroluminescent display device with the metal layer of 1.75 Å/s and the emission intensity of the electroluminescent display device with the metal layer of 2.7 Å/s.

TABLE 1

| the | | | | | | | | |
|---|---|---|---|---|---|---|---|---|
| deposition | | the refractive index n of | | | the refractive index k of | | | the reflectance of the |
| rate of the | | the metal layer | | | the metal layer | | | electroluminescent |
| metal layer | | 450 nm | 550 nm | 650 nm | 450 nm | 550 nm | 650 nm | display device |
| 3.5 | Å/s | 1.823 | 2.141 | 2.463 | 3.285 | 3.660 | 3.978 | 14.1% |
| 2.7 | Å/s | 2.242 | 2.562 | 2.854 | 3.136 | 3.294 | 3.482 | 14.0% |
| 1.75 | Å/s | 3.074 | 3.365 | 3.511 | 3.424 | 3.210 | 3.090 | 14.4% |

Table 2 shows a value of the color temperature of the electroluminescent display device when the metal layer (Al) is applied as the second electrode (cathode) according to the change in the deposition rate below.

As shown in Table 2 below, as the deposition rate of the metal layer increases, the value of the color temperature of the electroluminescent display device decreases.

Specifically, when the deposition rate of the metal layer is in the range of 1.7 Å/s to 2.0 Å/s, the value of color temperature of the electroluminescent display device may be higher than 8000 K and specifically, may be in the range of more than 8000 K and less than 8300 K. Also, when the deposition rate of the metal layer is in the range of 3.0 Å/s to 3.7 Å/s, the value of color temperature of the electroluminescent display device may be lower than 7100 K, and specifically, may be in the range of more than 6000 K and less than 7100 K.

Accordingly, the metal layer having the deposition rate within a range of 1.7 Å/s to 2.0 Å/s may be used as the first reflective layer 710, and the metal layer having the deposition rate within a range of 3.0 Å/s to 3.7 Å/s may be used as the second reflective layer 730 and the third reflective layer 740.

TABLE 2

| the deposition rate | the color |
|---|---|
| of the metal layer | temperature [K] |
| 1.7 | 8219 |
| 1.75 | 8186 |
| 1.8 | 8152 |
| 1.9 | 8082 |
| 2 | 8007 |
| 2.1 | 7928 |
| 2.2 | 7845 |
| 2.3 | 7758 |
| 2.4 | 7666 |
| 2.5 | 7571 |
| 2.6 | 7471 |
| 2.7 | 7301 |
| 2.8 | 7259 |
| 2.9 | 7146 |
| 3 | 7030 |
| 3.1 | 6909 |
| 3.2 | 6784 |
| 3.3 | 6655 |
| 3.4 | 6522 |
| 3.5 | 6510 |
| 3.6 | 6242 |
| 3.7 | 6096 |

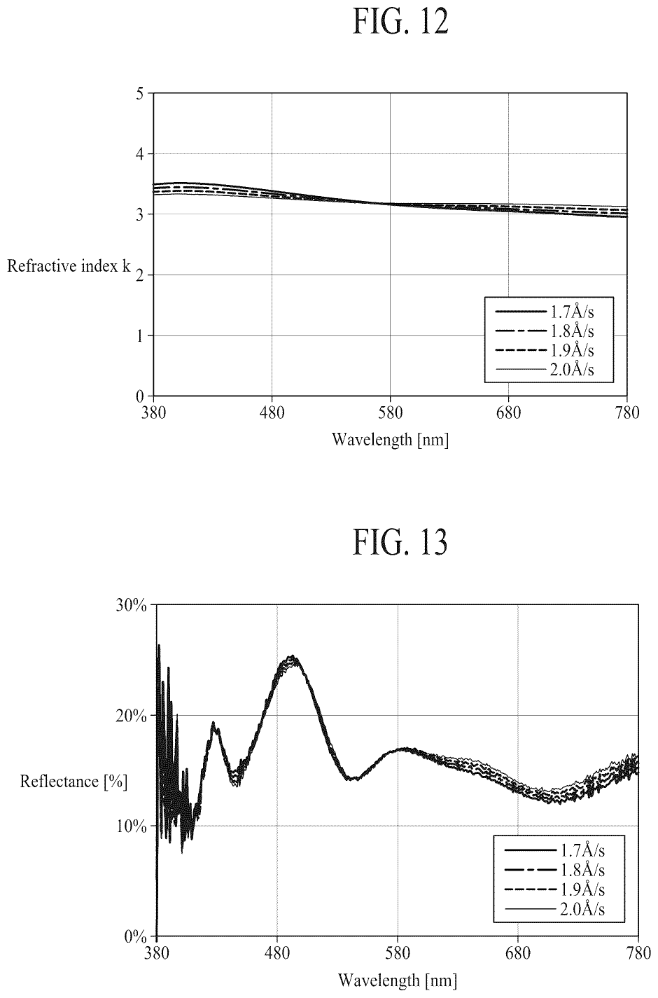

FIGS. 11 to 13 are graphs showing various optical characteristics according to a change in a deposition rate of aluminum (Al) as a metal layer in the range of 1.7 Å/s to 2.0 Å/s according to one or more embodiments of the present disclosure. Specifically, FIG. 11 is a graph showing a change in refractive index n for each wavelength band of a metal layer according to a change in a deposition rate in the range of 1.7 Å/s to 2.0 Å/s according to one or more embodiments of the present disclosure, FIG. 12 is a graph showing a change in refractive index k for each wavelength band of a metal layer according to a change in a deposition rate in the range of 1.7 Å/s to 2.0 Å/s according to one or more embodiments of the present disclosure, and FIG. 13 is a graph showing a change in reflectance for each wavelength band of an electroluminescent display device when a metal layer is applied as a second electrode (cathode) according to a change in a deposition rate in the range of 1.7 Å/s to 2.0 Å/s according to one or more embodiments of the present disclosure. The results according to FIGS. 11 to 13 are shown in Table 3 below.

As shown in FIG. 11 and Table 3, the refractive index n of the metal layer of 1.7 Å/s, the refractive index n of the metal layer of 1.8 Å/s, the refractive index n of the metal layer of 1.9 Å/s, and the refractive index n of the metal layer of 2.0 Å/s all gradually increase from the short wavelength band to the long wavelength band.

Specifically, in the short wavelength band (450 nm), the medium wavelength band (550 nm) and the long wavelength band (650 nm), the refractive index n of the metal layer having the lowest deposition rate of 1.75 Å/s is relatively the highest, and the refractive index n of the metal layer having the highest deposition rate of 2.0 Å/s is relatively the lowest. That is, in the short wavelength band (450 nm), the medium wavelength band (550 nm) and the long wavelength band (650 nm), as the deposition rate increases, the refractive index n of the metal layer gradually decreases.

As shown in FIG. 12 and Table 3, the refractive index k of the metal layer of 1.7 Å/s, the refractive index k of the metal layer of 1.8 Å/s, the refractive index k of the metal layer of 1.9 Å/s, and the refractive index k of the metal layer of 2.0 Å/s all gradually decrease from the short wavelength band to the long wavelength band.

At this time, from the short wavelength band to the long wavelength band, a decrease rate of the refractive index k of the metal layer of 1.7 Å/s is the largest, and a decrease rate of the refractive index k of the metal layer of 2.0 Å/s is the smallest.

Specifically, in the short wavelength band (450 nm) and the medium wavelength band (550 nm), the refractive index k of the metal layer having the lowest deposition rate of 1.7 Å/s is relatively the highest, and in the long wavelength band (650 nm), the refractive index k of the metal layer having the highest deposition rate of 2.0 Å/s is relatively the highest.

In the short wavelength band (450 nm) and the medium wavelength band (550 nm), the refractive index k may decrease as the deposition rate increases, and in the long wavelength band (650 nm), the refractive index k may increase as the deposition rate increases.

As shown in FIG. 13, the reflectance of the electroluminescent display device with a metal layer of 1.7 Å/s is relatively the highest in the short wavelength band 450 nm, and the reflectance of the electroluminescent display device with a metal layer of 2.0 Å/s is relatively the highest in the long wavelength band (650 nm).

In the short wavelength band (450 nm), as the deposition rate increases, the reflectance of the electroluminescent display device decreases, and in the long wavelength band (650 nm), as the deposition rate increases, the reflectance of the electroluminescent display device may increase.

TABLE 3

| the | | | | | | |
|---|---|---|---|---|---|---|
| deposition | the refractive index n of | | | the refractive index k of | | |
| rate of the | the metal layer | | | the metal layer | | |
| metal layer | 450 nm | 550 nm | 650 nm | 450 nm | 550 nm | 650 nm |
| 1.7 Å/s | 3.128 | 3.416 | 3.551 | 3.453 | 3.216 | 3.076 |
| 1.8 Å/s | 3.021 | 3.315 | 3.471 | 3.396 | 3.205 | 3.106 |
| 1.9 Å/s | 2.918 | 3.216 | 3.393 | 3.345 | 3.198 | 3.138 |
| 2.0 Å/s | 2.820 | 3.122 | 3.318 | 3.299 | 3.195 | 3.173 |

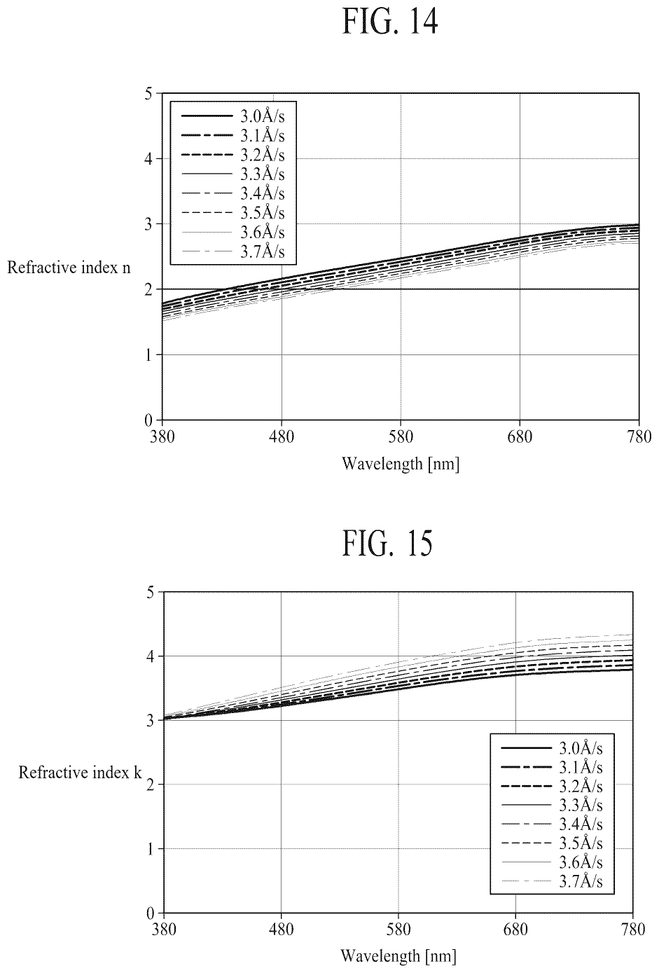

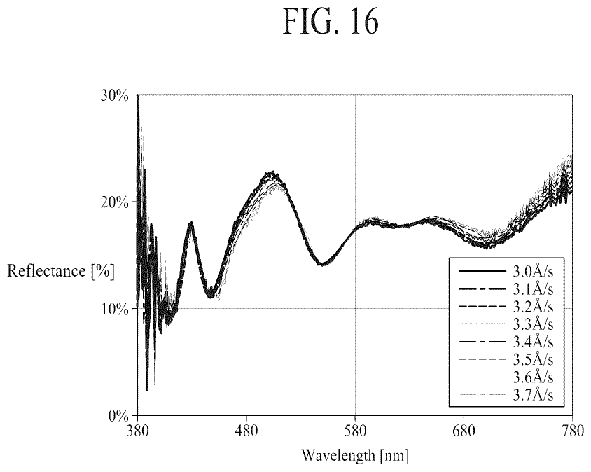

FIGS. 14 to 16 are graphs showing various optical characteristics according to a change in a deposition rate of aluminum (Al) as a metal layer in the range of 3.0 Å/s to 3.7 Å/s according to one or more embodiments of the present disclosure. Specifically, FIG. 14 is a graph showing a change in refractive index n for each wavelength band of a metal layer according to a change in a deposition rate in the range of 3.0 Å/s to 3.7 Å/s according to one or more embodiments of the present disclosure, FIG. 15 is a graph showing a change in refractive index k for each wavelength band of a metal layer according to a change in a deposition rate in the range of 3.0 Å/s to 3.7 Å/s according to one or more embodiments of the present disclosure, and FIG. 16 is a graph showing a change in reflectance for each wavelength band of an electroluminescent display device when a metal layer is applied as a second electrode (cathode) according to a change in a deposition rate in the range of 3.0 Å/s to 3.7 Å/s according to one or more embodiments of the present disclosure. The results according to FIGS. 14 to 16 are shown in Table 4 below.

As shown in FIG. 14 and Table 4, the refractive index n of the metal layers in a range of 3.0 Å/s to 3.7 Å/s all gradually increase from the short wavelength band to the long wavelength band.

Specifically, in the short wavelength band (450 nm), the medium wavelength band (550 nm) and the long wavelength band (650 nm), the refractive index n of the metal layer having the lowest deposition rate of 3.0 Å/s is relatively the highest, and the refractive index n of the metal layer having the highest deposition rate of 3.7 Å/s is relatively the lowest. That is, in the short wavelength band (450 nm), the medium wavelength band (550 nm) and the long wavelength band (650 nm), as the deposition rate increases, the refractive index n of the metal layer gradually decreases.

As shown in FIG. 15 and Table 4, the refractive index k of the metal layer in the range of 3.0 Å/s to 3.7 Å/s gradually increase from the short wavelength band to the long wavelength band.

Specifically, in the short wavelength band (450 nm), the medium wavelength band (550 nm) and the long wavelength band (650 nm), the refractive index k of the metal layer having the lowest deposition rate of 3.0 Å/s is relatively the lowest, and the refractive index k of the metal layer having the highest deposition rate of 3.7 Å/s is relatively the highest. That is, in the short wavelength band (450 nm), the medium wavelength band (550 nm) and the long wavelength band (650 nm), as the deposition rate increases, the refractive index k of the metal layer gradually increases.

As shown in FIG. 16, the reflectance of the electroluminescent display device with a metal layer of 3.0 Å/s is relatively the highest in the short wavelength band 450 nm, and the reflectance of the electroluminescent display device with a metal layer of 3.7 Å/s is relatively the highest in the long wavelength band (650 nm).

In the short wavelength band (450 nm), as the deposition rate increases, the reflectance of the electroluminescent display device decreases, and in the long wavelength band (650 nm), as the deposition rate increases, the reflectance of the electroluminescent display device may increase.

TABLE 4

| the | | | | | | |
|---|---|---|---|---|---|---|
| deposition | the refractive index n of | | | the refractive index k of | | |
| rate of the | the metal layer | | | the metal layer | | |
| metal layer | 450 nm | 550 nm | 650 nm | 450 nm | 550 nm | 650 nm |
| 3.0 Å/s | 2.055 | 2.377 | 2.690 | 3.150 | 3.400 | 3.650 |
| 3.1 Å/s | 2.000 | 2.322 | 2.640 | 3.166 | 3.443 | 3.711 |
| 3.2 Å/s | 1.950 | 2.271 | 2.592 | 3.187 | 3.491 | 3.774 |
| 3.3 Å/s | 1.904 | 2.224 | 2.547 | 3.214 | 3.543 | 3.840 |
| 3.4 Å/s | 1.861 | 2.181 | 2.504 | 3.247 | 3.599 | 3.907 |
| 3.5 Å/s | 1.823 | 2.141 | 2.463 | 3.285 | 3.660 | 3.978 |
| 3.6 Å/s | 1.789 | 2.105 | 2.425 | 3.329 | 3.724 | 4.050 |
| 3.7 Å/s | 1.758 | 2.072 | 2.389 | 3.379 | 3.793 | 4.125 |

According to one or more embodiments of the present disclosure, it is possible to implement low power reduction of the electroluminescent display device while having high efficiency and low reflection characteristics.

Although the embodiments of the present disclosure have been described in more detail with reference to the accompanying drawings, the present disclosure is not necessarily limited to these embodiments, and may be variously modified without departing from the technical idea of the present disclosure. Therefore, the embodiments disclosed in the present disclosure are not intended to limit the technical idea of the present disclosure, but to explain, and the scope of the technical idea of the present disclosure is not limited by these embodiments. Therefore, it should be understood that the above-described embodiments are exemplary and not limited in all respects. The scope of protection of the present disclosure should be interpreted by the claims, and all technical ideas within the equivalent scope should be interpreted as being included in the scope of the present disclosure.

What is claimed is:

1. An electroluminescent display device, comprising:
a sub-pixel including a light emitting area and a circuit area;
a first electrode in the light emitting area of the sub-pixel;
a light emitting layer on the first electrode in the light emitting area of the sub-pixel; and
a second electrode on the light emitting layer, the second electrode includes a first reflective layer overlapping the light emitting area and a second reflective layer overlapping the circuit area,
wherein a reflectance of a blue wavelength band of light of the first reflective layer is higher than a reflectance of the blue wavelength band of light of the second reflective layer.

2. The electroluminescent display device of claim 1, wherein a reflectance of a red wavelength band of light of the first reflective layer is lower than a reflectance of the red wavelength band of light of the second reflective layer.

3. The electroluminescent display device of claim 1, wherein the first reflective layer is non-overlapping with the circuit area, and the second reflective layer further overlaps the light emitting area.

4. The electroluminescent display device of claim 3, wherein the first reflective layer extends from the light emitting area to at least a portion of a boundary area that is between the light emitting area and the circuit area, and
the second reflective layer continuously extends from the light emitting area to the circuit area via the boundary area.

5. The electroluminescent display device of claim 3, wherein the first reflective layer is in contact with a first portion of an upper surface of the light emitting layer in the light emitting area, and the second reflective layer is in contact with a second portion of the upper surface of the light emitting layer in the circuit area.

6. The electroluminescent display device of claim 1, wherein the second electrode further includes a transmissive layer between the first reflective layer and the second reflective layer.

7. The electroluminescent display device of claim 6, wherein the transmissive layer has a same pattern as the first reflective layer or the second reflective layer.

8. The electroluminescent display device of claim 1, wherein the second electrode further includes a third reflective layer that overlaps the circuit area,
the third reflective layer having an upper surface that is aligned with an upper surface of the first reflective layer and is in contact with an upper surface of the light emitting layer, and
the reflectance of the blue wavelength band of light of the first reflective layer is higher than a reflectance of the blue wavelength band of light of the third reflective layer.

9. The electroluminescent display device of claim 8, wherein the second electrode further includes a transmissive layer that is between the first reflective layer and the second reflective layer in the light emitting area, and the transmissive layer is between the third reflective layer and the second reflective layer in the circuit area.

10. The electroluminescent display device of claim 1, wherein the first reflective layer and the second reflective layer include a same metal, and a reflectance of the first reflective layer for each wavelength band of light is different from a reflectance of the second reflective layer for each wavelength band of light.

11. The electroluminescent display device of claim 10, wherein a deposition rate of the first reflective layer is less than a deposition rate of the second reflective layer.

12. The electroluminescent display device of claim 10, wherein a refractive index of the first reflective layer is higher than a refractive index of the second reflective layer in wavelength bands of 450 nm, 550 nm, and 650 nm.

13. The electroluminescent display device of claim 10, wherein a refractive index of the first reflective layer is higher than a refractive index of the second reflective layer in a wavelength band of the 450 nm and the refractive index of the first reflective layer is lower than the refractive index of the second reflective layer in wavelength bands of the 550 nm and 650 nm.

14. An electroluminescent display device, comprising:
a first sub-pixel and a second sub-pixel emitting light of different colors;
a first electrode in the first sub-pixel;
a first electrode in the second sub-pixel;
a light emitting layer on the first electrode in the first sub-pixel and on the first electrode in the second sub-pixel; and
a second electrode in the first sub-pixel and the second sub-pixel and on the light emitting layer, the second electrode including a first reflective layer and a second reflective layer that is on the first reflective layer,
wherein the first reflective layer of the second electrode in the second sub-pixel is spaced apart from the first reflective layer of the second electrode in the first sub-pixel, and
wherein the second reflective layer is continuous from the first sub-pixel to the second sub-pixel.

15. The electroluminescent display device of claim 14, wherein each of a reflectance of the blue wavelength band of light of the first reflective layer of the second electrode in the first sub-pixel and a reflectance of the blue wavelength band of light of the first reflective layer of the second electrode in the second sub-pixel is higher than a reflectance of the blue wavelength band of light of the second reflective layer, and
a reflectance of the red wavelength band of light of the first reflective layer of the second electrode in the first sub-pixel and a reflectance of the red wavelength band of light of the first reflective layer of the second electrode in the second sub-pixel is lower than a reflectance of the red wavelength band of light of the second reflective layer.

16. The electroluminescent display device of claim 14, wherein the first reflective layer of the second electrode in the first sub-pixel and the first reflective layer of the second electrode in the second sub-pixel extend to a portion of a boundary area between the first sub-pixel and the second sub-pixel.

17. The electroluminescent display device of claim 14, wherein the first reflective layer of the second electrode in the first sub-pixel contacts a first portion of the light emitting layer in a first light emitting area of the first sub-pixel,
the first reflective layer of the second electrode in the second sub-pixel contacts a second portion of the light emitting layer in a second light emitting area of the second sub-pixel, and
the second reflective layer contacts a third portion of the light emitting layer in a boundary area between the first sub-pixel and the second sub-pixel.

18. The electroluminescent display device of claim 17, wherein the second electrode further includes a transmissive layer that is between the first reflective layer of the second electrode in the first sub-pixel and the second reflective layer and between the first reflective layer of the second electrode in the second sub-pixel and the second reflective layer, and
wherein the transmissive layer includes a same pattern as the first reflective layer of the second electrode in the first sub-pixel and the first reflective layer of the second electrode in the second sub-pixel.

19. The electroluminescent display device of claim 14, further comprising:
a third reflective layer in the boundary area, the third reflective layer between the first reflective layer of the second electrode in the first sub-pixel and the first reflective layer of the second electrode in the second sub-pixel,
wherein a reflectance of the blue wavelength band of light of the first reflective layer of the second electrode in the first sub-pixel and a reflectance of the blue wavelength band of light of the first reflective layer of the second electrode in the second sub-pixel is higher than a reflectance of the blue wavelength band of light of the third reflective layer, and
wherein each of a reflectance of the red wavelength band of light of the first reflective layer of the second electrode in the first sub-pixel and a reflectance of the red wavelength band of light of the first reflective layer of the second electrode in the second sub-pixel is lower than a reflectance of the red wavelength band of light of the third reflective layer.

20. The electroluminescent display device of claim 19, wherein the second electrode further includes a transmissive layer that is between the first reflective layer of the second electrode in the first sub-pixel and the second reflective layer and between the third reflective layer and the second reflective layer.

21. An electroluminescent display device, comprising:
a substrate; and
a sub-pixel on the substrate, the sub-pixel including:
a light emitting area that emits light;
a circuit area that controls light emission from the light emitting area;
a driving thin film transistor in the circuit area;
a first electrode extending from the light emitting area to the circuit area, the first electrode connected to the driving thin film transistor;
a light emitting layer on the first electrode in the light emitting area; and
a second electrode on the light emitting layer, the second electrode including a first reflective layer and a second reflective layer on the first reflective layer,
wherein the first reflective layer overlaps at least the light emitting area and the second reflective layer overlaps the light emitting area and the circuit area, and
wherein a reflectance of the first reflective layer is different than a reflectance of the second reflective layer.

22. The electroluminescent display device of claim 21, wherein the second electrode further includes a transmissive layer between the first reflective layer and a portion of the second reflective layer.

23. The electroluminescent display device of claim 22, wherein the sub-pixel further includes a boundary area between the light emitting area and the circuit area, the transmissive layer overlapping the light emitting area and a portion of the boundary area, and the first reflective layer overlapping the light emitting area and the portion of the boundary area.

24. The electroluminescent display device of claim 21, wherein the reflectance of the first reflective layer is higher than the reflectance of the second reflective layer for a wavelength band of blue light emitted from the light emitting layer, and
wherein the reflectance of the first reflective layer is lower than the reflectance of the second reflective layer for a wavelength band of red light emitted from the light emitting layer.

25. The electroluminescent display device of claim 21, wherein the sub-pixel further includes a boundary area between the light emitting area and the circuit area,
wherein the second electrode further includes a transmissive layer overlapping the light emitting area, the boundary area, and the circuit area,
wherein the first reflective layer overlaps the light emitting area and a first portion of the boundary area, and
wherein the second reflective layer overlaps the light emitting area, the boundary area, and the circuit area.

26. The electroluminescent display device of claim 25, wherein the second electrode further includes a third reflective layer that overlaps the circuit area and a second portion of the boundary area that is outside of the first portion,
wherein an upper surface of the third reflective layer is aligned with an upper surface of the first reflective layer.

27. The electroluminescent display device of claim 26, wherein the transmissive layer is on the first reflective layer and the third reflective layer in the boundary area, and the second reflective layer is on the transmissive layer in the boundary area.

28. The electroluminescent display device of claim 26, wherein the first reflective layer and the third reflective layer are in direct contact with an upper surface of the light emitting layer.

29. The electroluminescent display device of claim 26, wherein a reflectance of the third reflective layer is different than the reflectance of the first reflective layer for each wavelength band of light emitted from the light emitting layer.
